(19) United States
(12) Patent Application Publication
(10) Pub. No.: US 2013/0083500 A1
(43) Pub. Date: Apr. 4, 2013

(54) INTERFEROMETRIC COLOR MARKING

(71) Applicants: Christopher D. Prest, San Francisco, CA (US); Dermot J. Stratton, San Francisco, CA (US); Joseph C. Poole, San Francisco, CA (US); Matthew S. Scott, San Francisco, CA (US); Michael S. Nashner, San Jose, CA (US)

(72) Inventors: Christopher D. Prest, San Francisco, CA (US); Dermot J. Stratton, San Francisco, CA (US); Joseph C. Poole, San Francisco, CA (US); Matthew S. Scott, San Francisco, CA (US); Michael S. Nashner, San Jose, CA (US)

(21) Appl. No.: 13/250,660

(22) Filed: Sep. 30, 2011

(51) Int. Cl. H05K 5/00; B32B 3/00; B29B 13/08

(52) U.S. Cl. 361/757; 361/752; 264/405; 264/400; 428/195.1

(57) ABSTRACT

Techniques or processes for providing markings on products are disclosed. In one embodiment, the products have housings and the markings are to be provided on the housings. For example, a housing for a particular product can include an outer housing surface and the markings can be provided on the outer housing surface so as to be visible from the outside of the housing. The markings are able to be interferometric colors and/or black.

### BACKGROUND OF THE INVENTION

Consumer products, such as electronic devices, may be marked for notifying users of various kinds of different information. For example, it is common for electronic devices to be marked with a serial number, model number, copyright information and the like. Further, by marking electronic devices with a supplier's brand, consumers can identify the electronic devices as sourced from the supplier.

Printing or stamping process using ink pigments may be used for such marking. Although conventional ink pigment printing and stamping is useful for many situations, such techniques can be inadequate in the case of handheld electronic devices. The small form factor of handheld electronic devices, such as mobile phones, portable media players and Personal Digital Assistants (PDAs), requires that the marking be very small. In order for such small marking to be legible, the marking must be accurately and precisely formed. Unfortunately, however, conventional techniques are not able to offer sufficient accuracy and precision. Thus, there is a need for improved techniques to mark products.

### SUMMARY OF THE INVENTION

The invention pertains to techniques or processes for providing markings on products. In one embodiment, the products have housings and the markings are to be provided on the housings. For example, a housing for a particular product can include an outer housing surface and the markings can be provided on the outer housing surface so as to be visible from the outside of the housing. The markings provided on products can be textual and/or graphic. The markings can be formed with high resolution. The markings are also able to be interferometric colors and/or black, even on metal or bulk metallic glass surfaces.

In general, the markings (also referred to as annotations or labeling) provided on products according to the invention can be textual and/or graphic. The markings can be used to provide a product (e.g., a product's housing) with certain information. The marking can, for example, be use to label the product with various information. When a marking includes text, the text can provide information concerning the product (e.g., electronic device). For example, the text can include one or more of: name of product, trademark or copyright information, design location, assembly location, model number, serial number, license number, agency approvals, standards compliance, electronic codes, memory of device, and the like). When a marking includes a graphic, the graphic can pertain to a logo, a certification mark, standards mark or an approval mark that is often associated with the product. The marking can be used for advertisements to be provided on products. The markings can also be used for customization (e.g., user customization) of a housing of a product.

The invention can be implemented in numerous ways, including as a method, system, device, or apparatus. Several embodiments of the invention are discussed below.

As an electronic device housing, one embodiment of the invention can, for example, include at least a substrate of the electronic device housing, and interferometric color markings disposed on the substrate of the electronic device housing.

As a method for marking an electronic device housing, one embodiment can, for example, include at least providing a substrate of the electronic device housing, and directing radiant energy in preselected amounts for producing interferometric color markings on the substrate of the electronic device housing.

As another embodiment, an article can, for example, include at least a bulk metallic glass substrate, and markings disposed on the bulk metallic glass substrate.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIG. 1 is a diagram of a marking state machine according to one embodiment of the invention.

FIG. 2 is an illustration of a substrate having markings according to one embodiment.

FIG. 3 is a flow diagram of marking processes according to one embodiment.

FIGS. 4A-4C are diagrams illustrating marking of a substrate according to one embodiment.

FIG. 5 is a table illustrating exemplary laser operation parameters for interferometric color marking of substrates according to one embodiment.

FIG. 6 is a diagram illustrating interferometric color markings, each having a respective predetermined interferometric color response to incident light.

FIGS. 7A and 7B diagrams of pixels, comprising subpixels of different interferometric colors.

FIG. 8 is a flow diagram of a marking process according to one embodiment.

FIG. 9A is a diagrammatic representation of an exemplary product housing.

FIG. 9B illustrates the product housing having markings according to one exemplary embodiment.

### DETAILED DESCRIPTION OF EMBODIMENTS OF THE INVENTION

The invention pertains to techniques or processes for providing markings on products. In one embodiment, the products have housings and the markings are to be provided on the housings. For example, a housing for a particular product can include an outer housing surface and the markings can be provided on the outer housing surface so as to be visible from the outside of the housing. The markings provided on products can be textual and/or graphic. The markings can be formed with high resolution. The markings are also able to be interferometric colors and/or black, even on metal or bulk metallic glass surfaces.

It should understood that interferometric colors are distinguished from pigmented colors. Similarly, interferometric color markings are distinguished from markings using colored ink or paint pigments. Thin film optical interference effects (or other interference effects) predominate in interferometric colors and in interferometric color markings.

A substantially transparent marking layer may be an optical thin film, having a thickness on the order of visible light wavelengths. Incident light can be reflected and re-reflected within the thickness of the marking layer for producing an optical response from an optical interference effect. Interferometric color markings may each comprise a respective marking layer having a predetermined layer thickness for substantially determining interferometric color response to incident light. For example interferometric color markings can have interferometric color responses such as yellow, orange, purple, blue or green, which can be substantially determined by marking layer thickness.

Radiant energy may be directed in preselected amounts for producing interferometric color markings on a substrate of an electronic device housing. In particular, directing the radiant energy in preselected amounts may produce marking layers having predetermined layer thickness. This may in turn substantially determine interferometric color response of the markings to incident light, as just discussed.

Directing radiant energy in the preselected amounts for producing the interferometric color markings on the substrate may comprise laser etching regions of the substrate. The interferometric color markings, or more particularly the marking layers of the interferometric color markings, may comprise oxide layers grown in response to heat of laser etching. More generally, interferometric color markings may be formed on the substrate in response to heat from directing the radiant energy to the substrate.

Radiant energy may be directed in a sufficient amount for producing ultrasmall light trapping structures arranged on selected regions of the substrate, so as to provide a substantially black appearance to the selected regions. The sufficient amount of the radiant energy for producing substantially black marking may be substantially greater than the preselected amounts of the radiant energy for producing the previously discussed interferometric color markings.

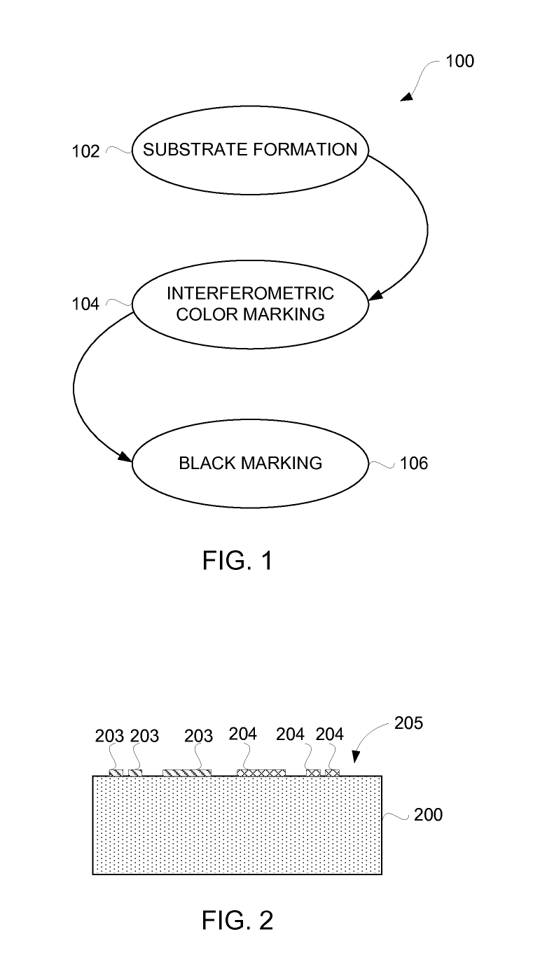

Exemplary embodiments of the invention are discussed below with reference to FIGS. 1-9B. However, those skilled in the art will readily appreciate that the detailed description given herein with respect to these figures is for explanatory purposes as the invention extends beyond these limited embodiments.

FIG. 1 is a diagram of a marking state machine 100 according to one embodiment of the invention. The marking state machine 100 reflects three (3) basic states associated with marking a housing substrate of an electronic device. Specifically, the marking can mark a housing of an electronic device, such as a portable electronic device.

The marking state machine 100 includes a substrate formation state 102. At the substrate formation state 102, a substrate can be obtained or produced. For example, the substrate can represent at least a portion of a housing surface of an electronic device. Next, the marking state machine 100 can transition to an interferometric color marking state 104. At the interferometric color marking state 104, interferometric color marking can be produced on the substrate. Next, the marking state machine 100 can transition to a black marking state 106. At the black marking state 106, black marking can be produced on the substrate. The interferometric color marking and/or black marking can be provided with high resolution.

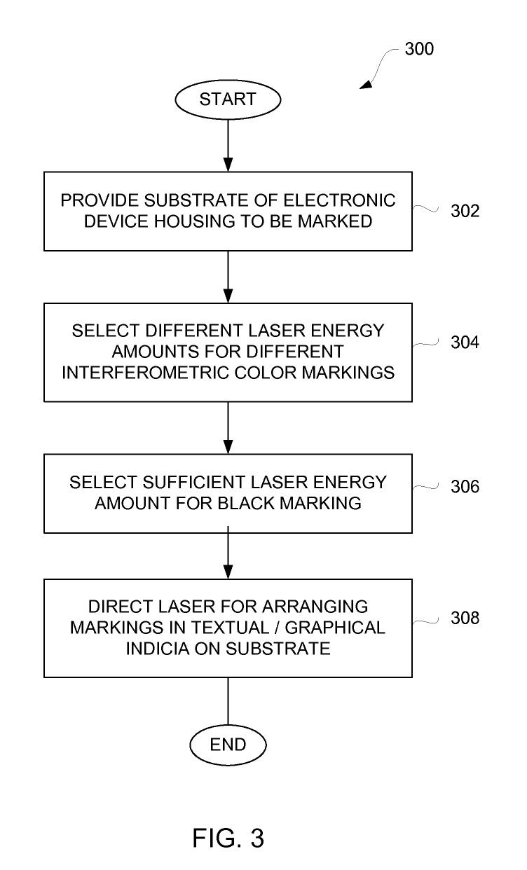

FIG. 2 is an illustration of a substrate 200, which may have interferometric color markings 203 and/or black markings 204 disposed on surface 205 of the substrate 200. Substrate 200 may have interferometric color marking layers 203 and/or black marking layers 204 disposed on the substrate. Interferometric color markings 203, or more particularly interferometric color marking layers 203 may comprise oxide layers 203. Black markings 204, or more particularly black marking layers 204, may comprise ultrasmall light trapping structures arranged on selected regions of the substrate 200, so as to provide the substantially black appearance to the selected regions.

The substrate 200 may be substantially reflective to light. The substrate 200 may comprise metal, and in particular may comprise metallic glass or bulk metallic glass. The metallic glass or bulk metallic glass may comprise a suitable zirconium based alloy, of various compositions known to those skilled in the art. The substrate may be substantially gray, and is depicted in the figures using stippling.

The substrate 200 can represent at least a portion of a housing of an electronic device. The inteferometric color markings 203 and/or black markings 204 being provided to the substrate 200 can provide text and/or graphics to an outer housing surface of a portable electronic device. The marking techniques are particularly useful for smaller scale portable electronic devices, such as handheld electronic devices. Examples of handheld electronic devices include mobile telephones (e.g., cell phones), Personal Digital Assistants (PDAs), portable media players, remote controllers, pointing devices (e.g., computer mouse), game controllers, etc.

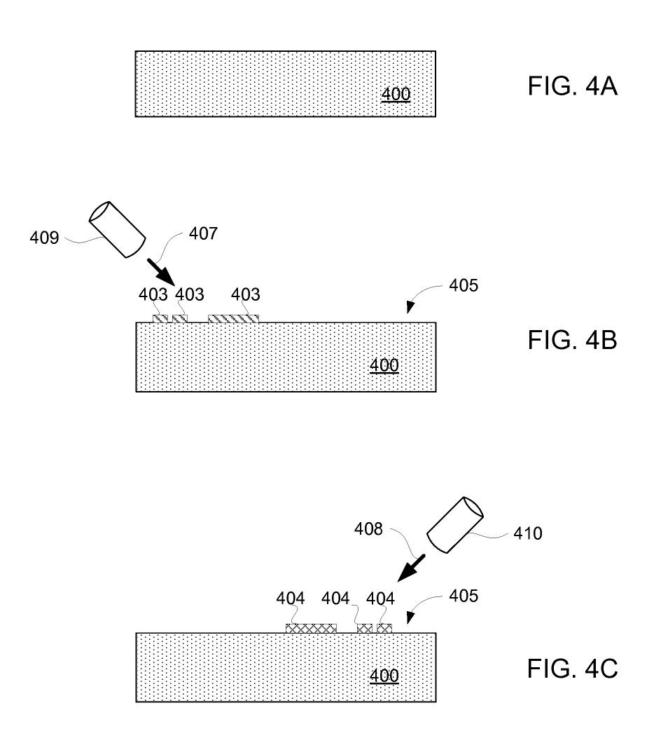

FIG. 3 is a flow diagrams of a marking processes 300 according to one embodiment. The marking process 300 can be performed on a housing substrate of an electronic device that is to be marked. The marking processes 300 is, for example, suitable for applying text or graphics to a housing (e.g., an outer housing surface) of an electronic device. The marking can be provided such that it is visible to users of the electronic device. However, the marking can be placed in various different positions, surfaces or structures of the electronic device.

The marking process can provide a substrate for an article to be marked. The substrate can be a metal structure, for example a bulk metallic glass structure. The metal structure can pertain to a metal housing for an electronic device, such as a portable electronic device, to be marked. The metal structure can be formed of one metal layer, which may comprise metallic glass or bulk metallic glass. The metal structure can also be formed of multiple layers of different materials, where at least one of the multiple layers is a metal layer, a metallic glass layer, or a bulk metallic glass layer.

In accordance with the marking process 300 shown in FIG. 3, the process may begin with providing 302 the housing substrate of the electronic device to be marked. After the substrate has been provided 302, different radiant energy amounts (i.e. different laser energy amounts) may be selected 304. Selection 304 of various different radiant energy amounts may correspond to various different desired interferometric colors. More particularly, selection 304 of various different radiant energy amounts may correspond to various different desired inteferometric color markings.

Further, as shown in the process 300 of FIG. 3, selection 306 of a sufficiently high radiant energy amount (i.e. sufficiently high laser energy amount) may correspond to producing ultrasmall light trapping structures for arrangement on selected regions of the substrate, so as to provide a desired substantially black appearance to the selected regions of the substrate. In other words, selection 306 the sufficiently high radiant energy amount may correspond to desired black markings. The sufficient amount of the radiant energy for producing the substantially black marking may be substantially greater than the preselected amounts of the radiant energy for producing the interferometric color markings.

The radiant energy (i.e. the laser energy) may be directed 308 for arranging the interferometric color markings and/or black markings in textual or graphical indicia on the substrate of the electronic device housing. The radiant energy (i.e. the laser energy) may be directed 308 in preselected amounts for producing interferometric color markings on the substrate of the electronic device housing. This may comprise laser etching of selected regions of the substrate. Directing 308 radiant energy (i.e. laser energy) in the preselected amounts 308 may produce marking layers having predetermined layer thicknesses. Further, directing 308 radiant energy (i.e. laser energy) in sufficiently high amount can produce the substantially black marking on the substrate of the electronic device housing. Following the directing block 308, the marking process 300 shown in FIG. 3 can end.

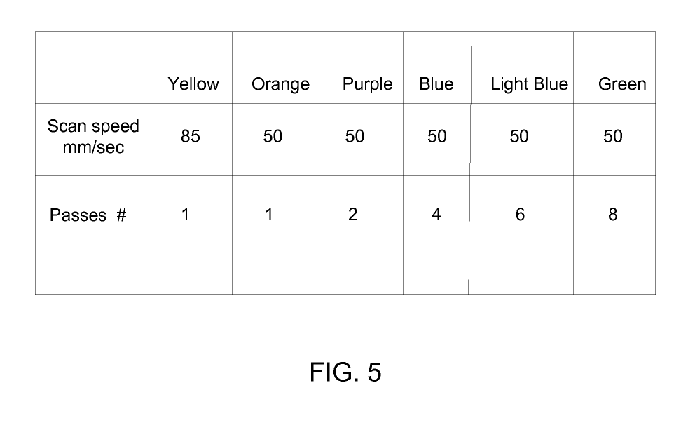

FIGS. 4A-4C are diagrams illustrating marking of a housing substrate 400 according to one embodiment. In FIG. 4A, housing substrate 400 is provided for marking. As examples, the housing substrate 400 may be formed of metal, metallic glass, or bulk metallic glass. In FIGS. 4A-4C the housing substrate 400 may be substantially gray, and is depicted in the FIGS. 4A-4C using stippling.

FIG. 4B illustrates interferometric color markings 403 (depicted with left to right hatching) that may be formed on a surface 405 of the housing substrate 400. The interferometric color markings 403 may formed by suitably selected amounts of radiant energy 407 (i.e. laser energy 407) produced by a suitably selected and operated source 409 (i.e. laser 409). The laser 409 may include a galvanometer mirror or other arrangement for raster scanning a spot of the laser energy over the surface 405 of the housing surface, so as to form the interferometric color markings 403 into a rasterized depiction of color interferometric marking indicia. Suitable pitch between raster scan lines of the scanning spot for the color interferometric markings 403 may be selected.

The radiant energy 407 (i.e. the laser energy 407 from laser 409) may be directed in preselected amounts for producing desired interferometric color markings 403 on the substrate 400 of the electronic device housing. This may comprise laser etching of selected regions of the substrate 400. Directing radiant energy 407 (i.e. laser energy 407) in the preselected amounts may produce marking layers 403 having predetermined layer thicknesses.

Alternatively or additionally, FIG. 4C illustrates substantially black markings 404 (depicted with cross hatching) that may be formed on surface 405 of the housing substrate 400. The substantially black markings 404 may be formed by selecting sufficiently high amounts of radiant energy 408 (i.e. laser energy 408) produced by a suitably selected and operated source 410 (i.e. laser 410). Laser etched regions 404 of the substrate 400 may appear substantially black. Ultrasmall light trapping structures 404 can be arranged on selected regions of the substrate 400 so as to provide the substantially black appearance to the selected regions. The laser 410 may include a galvanometer mirror or other arrangement for raster scanning a spot of the laser energy 408 over the surface 405 of the housing surface, so as to form the substantially black markings 404 into a rasterized depiction of black marking indicia. Suitable pitch between raster scan lines of the scanning spot for the substantially black markings 404 may be selected. By selective direction of the radiant energy 408 (i.e. laser energy 408) substantially black markings 404 can be arranged in a preselected halftone pattern on the substrate 400 of the electronic device housing.

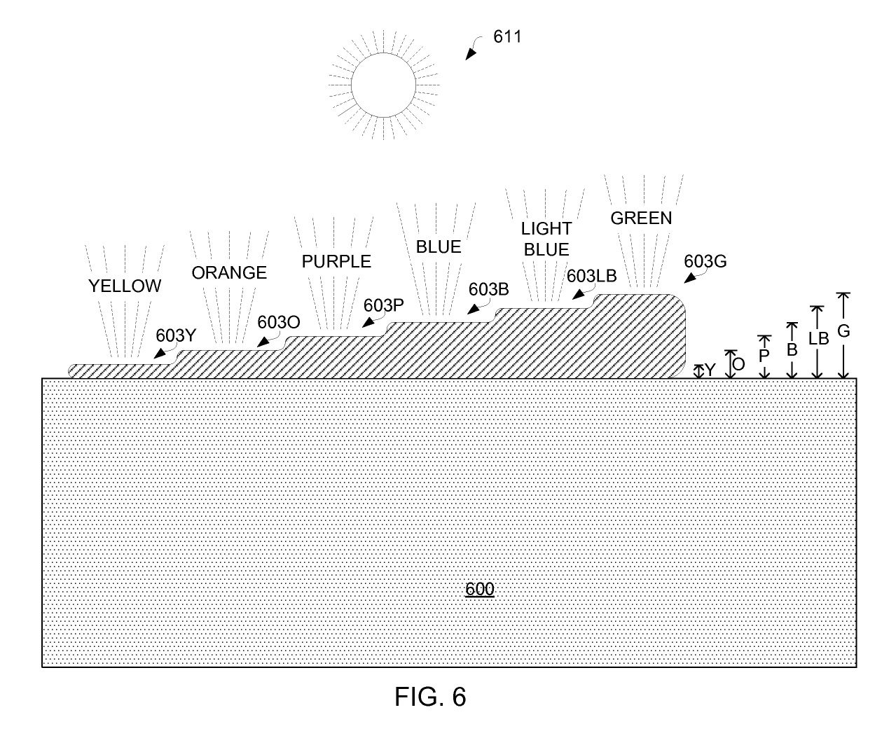

FIG. 5 is a table illustrating exemplary laser operation parameters for interferometric color marking of the housing substrate comprising bulk metallic glass. A FOBA DP20GS YVO4 laser marking machine may be used, which is available from FOBA Technology and Services GmbH, having offices at 159 Swanson Road, Boxborough, Mass.

For the FOBA DP20GS YVO4 laser marking machine, average power may be one Watt. Laser wavelength may be 1064 nanometers. Laser pulse width may be 40 nanoseconds. Laser pulse repetition frequency may be 100 kilohertz. Laser pulse energy may be ten microJoules. Laser pulse peak power may be a quarter of a kilowatt. Laser spot size may be 90 microns. Laser fluence for each pass may be two tenths of a Joule per square centimeter. Irradiance for each pass may be 0.0039 Gigawatts per square centimeter. Line spacing may be 15 microns.

As a general matter, increasing dosing of radiant energy (i.e. laser energy) increases inteferometric color marking layer thickness (i.e. oxide layer thickness). Inteferometric color marking layer thickness (i.e. oxide layer thickness) can substantially determine interferometric color response to incident light. As shown in the table of FIG. 5, a relatively low energy dosing using a scan speed of 85 millimeters per second, and just one scan pass, can grow a relatively thin layer for the interferometric yellow marking layer, which can produce the interferometric yellow response to incident light. Increasing energy dosing using a scan speed of 50 millimeters per second, and just one scan pass, can grow a relatively thicker layer for the interferometric orange marking layer, which can produce the interferometric orange response to incident light. Increasing energy dosing using a scan speed of 50 millimeters per second, and now two scan passes, can grow a relatively thicker layer for the interferometric purple marking layer, which can produce the interferometric purple response to incident light.

Similarly, increasing energy dosing using a scan speed of 50 millimeters per second, and four scan passes, can grow a relatively thicker layer for the interferometric blue marking layer, which can produce the interferometric blue response to incident light. Increasing energy dosing using a scan speed of 50 millimeters per second, and six scan passes, can grow a relatively thicker layer for the interferometric light blue marking layer, which can produce the interferometric light blue response to incident light. Increasing energy dosing using a scan speed of 50 millimeters per second, and eight scan passes, can grow a relatively thicker layer for the interferometric green marking layer, which can produce the interferometric green response to incident light.

The sufficient amount of the radiant energy for producing the substantially black markings may be substantially greater than the preselected amounts of the radiant energy for producing the interferometric color markings, as just discussed. Accordingly, for the substantially black markings, a relatively higher average power of two Watts may be selected on the FOBA DP20GS YVO4 laser marking machine. Laser wavelength may be 1064 nanometers. Laser pulse width may be 40 nanoseconds. Laser pulse repetition frequency may be 60 kilohertz. Laser pulse energy may be thirty microJoules. Laser pulse peak power may be 0.83 kilowatts. Laser spot size may be 40 microns. Laser fluence for each pass may be 2.7 Joule per square centimeter. Irradiance for each pass may be 0.066 Gigawatts per square centimeter. Line spacing may be 15 microns. Scan speed may be 200 millimeters per second. Number of passes may be two passes.

It should be understood that all of the foregoing laser operating parameters are exemplary, and that various other laser operating parameters may be selected to provide the amounts of laser energy for interferometric color and/or black marking of the housing substrate.

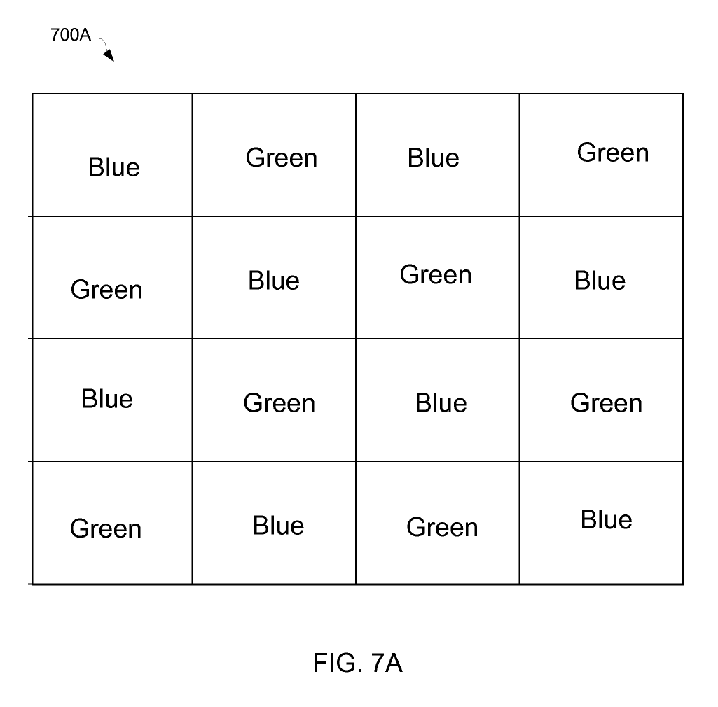

FIG. 6 is a diagram illustrating interferometric color markings 603Y, 603O, 603P, 603B, 603LB, 603G, each having a respective predetermined interferometric color response to incident light 611. Interferometric color markings 603Y, 603O, 603P, 603B, 603LB, 603G may each comprise a respective marking layer 603Y, 603O, 603P, 603B, 603LB, 603G having predetermined layer thicknesses Y”, “O”, “P”, “B”, “LB” and “G” for substantially determining interferometric color response to incident light 611.

For example interferometric color markings 603Y, 603O, 603P, 603B, 603LB, 603G can have interferometric color responses such as yellow, orange, purple, blue, light blue, green, which can be substantially determined by marking layer thicknesses “Y”, “O”, “P”, “B”, “LB” and “G” as shown in FIG. 6. In FIG. 6 interferometric color responses are depicted using legends for yellow, orange, purple, blue, light blue and green, which are each accompanied by dashed lines radiating from the interferometric color markings 603Y, 603O, 603P, 603B, 603LB, 603G.

Marking layers 603Y, 603O, 603P, 603B, 603LB, 603G may be substantially transparent optical thin films, having thicknesses Y”, “O”, “P”, “B”, “LB” and “G” on the order of visible light wavelengths. For example, auger electron spectroscopy analysis shows the following: the green interferometric color marking 603G can have a marking layer thickness “G” (i.e. oxide layer thickness “G”) of approximately 497.5 nanometers (which correlates well with a full wavelength of the green inteferometric color response); and the blue interferometric color marking 603B can have a marking layer thickness “B” (i.e. oxide layer thickness “B”) of approximately 472.5 nanometers (which correlates well with a full wavelength of the blue inteferometric color response).

Marking layer thicknesses are not limited to correlation with just one full wavelength of the inteferometric color responses. Marking layer thicknesses may correlate with half wavelengths of the inteferometric color responses. For example yellow interferometric color marking 603Y can have a marking layer thickness “Y” (i.e. oxide layer thickness “G”), which may correlate with a half wavelength of the yellow inteferometric color response. Orange interferometric color marking 603O can have a marking layer thickness “O” (i.e. oxide layer thickness “O”), which may correlate with a half wavelength of the orange inteferometric color response. Further, it is theorized that marking layer thicknesses could possibly be made to correlate with quarter wavelengths of the interferometric color responses. It is theorized that marking layer thicknesses could possibly be made to correlate with integer multiples of the foregoing (i.e. integer multiples of full, half and/or quarter wavelengths of the interferometric color responses.)

Incident light 611 can be reflected and re-reflected within the thicknesses of the marking layers 603Y, 603O, 603P, 603B, 603LB, 603G for producing optical responses from optical interference effects. Housing substrate 600 may be substantially reflective. Housing substrate 600 may comprise bulk metallic glass.

As mentioned previously herein, formation of the interferometric color markings 603Y, 603O, 603P, 603B, 603LB, 603G can be produced by directing radiant energy in preselected amounts. In particular, directing the radiant energy in preselected amounts may produce the marking layers 603Y, 603O, 603P, 603B, 603LB, 603G having predetermined layer thicknesses “Y”, “O”, “P”, “B”, “LB” and “G”. This may in turn substantially determine the interferometric color response of the markings to incident light 611, as just discussed.

As mentioned previously, directing radiant energy in the preselected amounts for producing the interferometric color markings 603Y, 603O, 603P, 603B, 603LB, 603G on the substrate may comprise laser etching regions of the substrate 600. The interferometric color markings 603Y, 603O, 603P, 603B, 603LB, 603G, or more particularly the marking layers 603Y, 603O, 603P, 603B, 603LB, 603G of the interferometric color markings, may comprise oxide layers grown in response to heat of laser etching. More generally, interferometric color markings 603Y, 603O, 603P, 603B, 603LB, 603G may be formed on the substrate in response to heat from directing the radiant energy to the substrate 600.

Heat of laser etching may produce a quasi-ordered structure of ultrasmall features in the interferometric color markings 603Y, 603O, 603P, 603B, 603LB, 603G. Accordingly, the interferometric color markings 603Y, 603O, 603P, 603B, 603LB, 603G may have responses to omnidirectional incident light 611, wherein the responses are substantially invariant with viewing angle. In other words, the interferometric color markings 603Y, 603O, 603P, 603B, 603LB, 603G may be substantially non-iridescent.

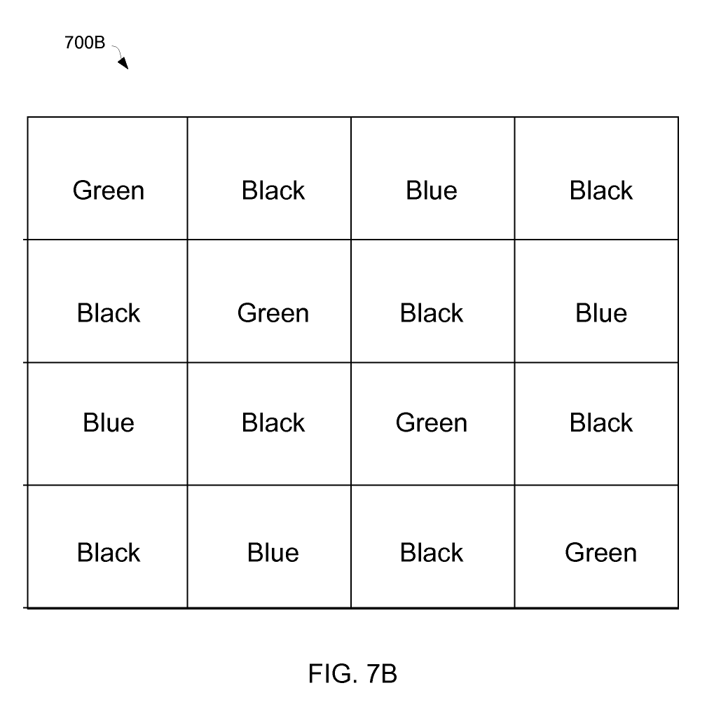

FIGS. 7A and 7B diagrams of pixels, comprising subpixels of different interferometric colors. For example, FIG. 7A shows a pixel 700A of a four by four array of blue and green interferometric color markings, which comprise sixteen subpixels of different interferometric colors (i.e. blue and green). In FIG. 7A the interferometric color markings comprising subpixels of different interferometric colors are depicted using legends for Blue and Green.

FIG. 7B shows another pixel 700B of a four by four array of sixteen subpixels. FIG. 7B shows four blue and four green interferometric color markings, which comprise eight subpixels of different interferometric colors (i.e. green and blue). In FIG. 7B, the interferometric color markings comprising subpixels of different interferometric colors are depicted using legends for Green and Blue. FIG. 7B further shows eight substantially black markings, comprising eight substantially black subpixels, arranged in a preselected halftone pattern.

In FIGS. 7A and 7B, groupings of adjacent subpixels are organized in preselected arrangements to provide pixels 700A, 700B each having a respective preselected color appearance. For example, in FIG. 7A a grouping of sixteen adjacent subpixels are organized in a preselected arrangement of blue and green to provide a pixel 700A having a preselected cyan color appearance (mixing blue and green.) In FIG. 7B a grouping of sixteen adjacent subpixels are organized in a preselected arrangement of green and blue, along with black halftoning to provide a pixel 700B having a preselected dark cyan color appearance (mixing green and blue colors, while further employing black halftoning.)

Pixels and pixel appearance are not limited to the foregoing examples. Other interferometric color marking combinations may be employed with beneficial results. For example, any one of the primary color interferometric markings (such as one of blue or green) may be combined with any one of the other interferometric color markings (such as yellow or purple), so as to provide pixels having other preselected color appearances (blue-yellow, blue-purple, green-yellow, or green-purple).

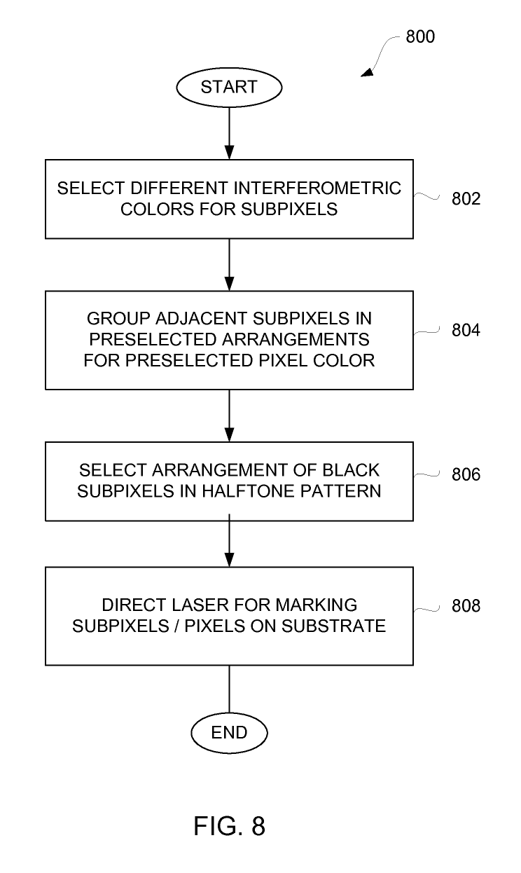

FIG. 8 is a flow diagram of a marking process 800 according to one embodiment. In accordance with the marking process 800 shown in FIG. 8, the process may begin with selecting 802 different interferometric colors for subpixels of the interferometric color markings. The process 800 may continue with organizing groupings 804 of adjacent subpixels in preselected arrangements to provide pixels having a preselected color appearance. The process 800 may continue with selecting 806 an arrangement of black subpixels in a halftone pattern. The process 800 may continue with selectively directing 808 a laser to mark the arrangements of subpixels and pixels on a substrate. Following the directing block 808, the marking process 800 shown in FIG. 8 can end.

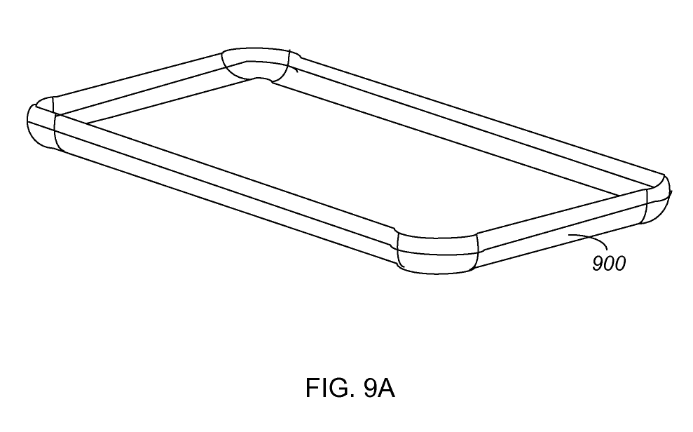

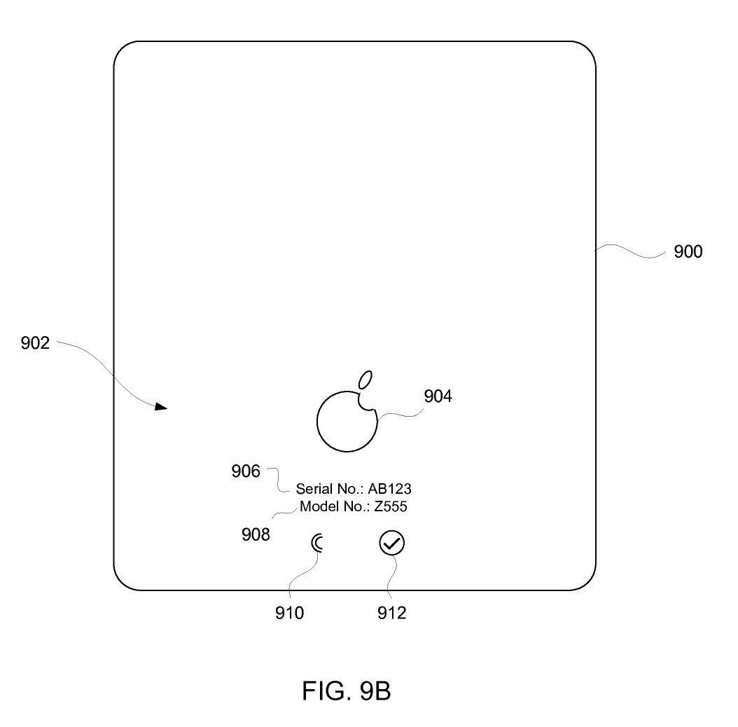

FIG. 9A is a diagrammatic representation of an exemplary product housing 900. The housing may be formed using metal, metallic glass or bulk metallic glass. The housing 900 may be a housing that is to be a part of an overall assembly, as for example a bottom of a cell phone assembly or portable media player.

FIG. 9B illustrates the product housing 900 having markings 902 according to one exemplary embodiment. The markings 902 can be inteferometric color markings and/or substantially black markings in accordance with the inteferometric color markings and/or substantially black markings as discussed previously herein. In this example, the labeling includes a logo graphic 904, serial number 906, model number 908, and certification/approval marks 910 and 912.

The marking processes described herein are, for example, suitable for applying text or graphics to a housing surface (e.g., an outer housing surface) of an electronic device. The marking processes are, in one embodiment, particularly well-suited for applying text and/or graphics to an outer housing surface of a portable electronic device. Examples of portable electronic devices include mobile telephones (e.g., cell phones), Personal Digital Assistants (PDAs), portable media players, remote controllers, pointing devices (e.g., computer mouse), game controllers, etc. The portable electronic device can further be a hand-held electronic device. The term hand-held generally means that the electronic device has a form factor that is small enough to be comfortably held in one hand. A hand-held electronic device may be directed at one-handed operation or two-handed operation. In one-handed operation, a single hand is used to both support the device as well as to perform operations with the user interface during use. In two-handed operation, one hand is used to support the device while the other hand performs operations with a user interface during use or alternatively both hands support the device as well as perform operations during use. In some cases, the hand-held electronic device is sized for placement into a pocket of the user. By being pocket-sized, the user does not have to directly carry the device and therefore the device can be taken almost anywhere the user travels (e.g., the user is not limited by carrying a large, bulky and often heavy device).

This application also references: (i) U.S. patent application Ser. No. 13/021,641, filed Feb. 4, 2011, and entitled “Marking of Product Housings,” (ii) U.S. patent application Ser. No. 12/895,814, filed Sep. 30, 2010, and entitled “Sub-Surface Marking of Product Housings,” (iii) U.S. patent application Ser. No. 12/895,591 , filed Sep. 30, 2010, and entitled “Cosmetic Conductive Laser Etching,” (iv) U.S. patent application Ser. No. 12/895,384, filed Sep. 30, 2010, and entitled “Sub-Surface Marking of Product Housings,” (v) U.S. patent application Ser. No. 12/643,772, filed Dec. 21, 2009, and entitled “Sub-Surface Marking of Product Housings,” (vi) U.S. patent application Ser. No. 12/569,810, filed Sep. 29, 2009, and entitled “Techniques for Marking Product Housings” which are hereby incorporated herein by reference.

The various aspects, features, embodiments or implementations of the invention described above can be used alone or in various combinations.

Different aspects, embodiments or implementations may, but need not, yield one or more of the following advantages. One advantage of the invention is that durable, high precision markings can be provided to product housings. Another advantage of the invention is that interferometric color markings can have a highly saturated or distinctive appearance. Another advantage is that the marking techniques can be used on bulk metallic glass. Another advantage is that the marking techniques are effective for surfaces that are flat or curved.

The many features and advantages of the present invention are apparent from the written description. Further, since numerous modifications and changes will readily occur to those skilled in the art, the invention should not be limited to the exact construction and operation as illustrated and described. Hence, all suitable modifications and equivalents may be resorted to as falling within the scope of the invention.

What is claimed is:

1. An electronic device housing comprising:
a substrate of the electronic device housing; and
interferometric color markings disposed on the substrate of the electronic device housing.

2. An electronic device housing as recited in claim 1 wherein the interferometric color markings comprise laser etched regions of the substrate.

3. An electronic device housing as recited in claim 1 wherein the substrate of the electronic device housing comprises metallic glass.

4. An electronic device housing as recited in claim 1 wherein the substrate of the electronic device housing comprises bulk metallic glass.

5. An electronic device housing as recited in claim 1 wherein each of the interferometric color markings comprises a respective marking layer having a respective predetermined layer thickness.

6. An electronic device housing as recited in claim 1 wherein each of the interferometric color markings comprises a respective oxide layer.

7. An electronic device housing as recited in claim 1 wherein each of the interferometric color markings has a respective predetermined interferometric color response to incident light.

8. An electronic device housing as recited in claim 1 wherein the interferometric color markings have interferometric color responses selected from yellow, orange, purple, blue or green.

9. An electronic device housing as recited in claim 1 further comprising substantially black markings disposed on the substrate of the electronic device housing.

10. An electronic device housing as recited in claim 1 further comprising laser etched regions of the substrate that are substantially black.

11. An electronic device housing as recited in claim 1 further comprising light trapping structures arranged on selected regions of the substrate so as to provide a substantially black appearance to the selected regions.

12. An electronic device housing as recited in claim 1 further comprising substantially black markings arranged in a preselected halftone pattern on the substrate of the electronic device housing.

13. An electronic device housing as recited in claim 1 wherein the interferometric color markings are arranged in textual or graphical indicia on the substrate of the electronic device housing.

14. An electronic device housing as recited in claim 1,
wherein the interferometric color markings comprise subpixels of different interferometric colors; and
wherein groupings of adjacent subpixels are organized in preselected arrangements to provide pixels each having a respective preselected color appearance.

15. An electronic device housing as recited in claim 1 wherein the interferometric color markings are substantially non-iridescent.

16. An electronic device housing as recited in claim 1 wherein the interferometric color markings have responses to omnidirectional incident light, wherein the responses are substantially invariant with viewing angle.

17. An electronic device housing as recited in claim 1 wherein each of the interferometric color markings has a quasi-ordered structure.

18. A method for marking an electronic device housing, comprising:
providing a substrate of the electronic device housing; and
directing radiant energy in preselected amounts for producing interferometric color markings on the substrate of the electronic device housing.

19. A method as recited in claim 18 wherein directing radiant energy in preselected amounts for producing interferometric color markings on the substrate comprises laser etching regions of the substrate.

20. A method as recited in claim 18 wherein the substrate of the electronic device housing comprises bulk metallic glass.

21. A method as recited in claim 18 wherein directing radiant energy in preselected amounts produces marking layers having predetermined layer thicknesses.

22. A method as recited in claim 18 wherein directing the radiant energy comprises arranging the interferometric color markings in textual or graphical indicia on the substrate of the electronic device housing.

23. A method as recited in claim 18 further comprising:
selecting different interferometric colors for subpixels of the interferometric color markings; and
organizing groupings of adjacent subpixels in preselected arrangements to provide pixels having a preselected color appearance.

24. A method as recited in claim 18 further comprising directing radiant energy in a sufficient amount for producing substantially black marking on the substrate of the electronic device housing.

25. A method as recited in claim 18 wherein the sufficient amount of the radiant energy for producing the substantially black marking is substantially greater than the preselected amounts of the radiant energy for producing the interferometric color markings.

26. An article comprising:
a bulk metallic glass substrate; and
markings disposed on the bulk metallic glass substrate.

27. An article as recited in claim 25 wherein the markings comprise interferometric color markings.

28. An article as recited in claim 25 wherein the markings comprise substantially black markings.

29. An article as recited in claim 25 wherein the markings comprise laser etched regions of the bulk metallic glass substrate.
